(19) United States
(12) Patent Application Publication
(10) Pub. No.: US 2016/0168700 A1
(43) Pub. Date: Jun. 16, 2016

(54) Systems, Devices, and/or Methods for Deposition of Metallic and Ceramic Coatings

(71) Applicant: Directed Vapor Technologies International, Inc., Charlottesville, VA (US)

(72) Inventor: Derek Hass, Charlottesville, VA (US)

(73) Assignee: Directed Vapor Technologies International, Inc., Charlottesville, VA (US)

(21) Appl. No.: 14/962,893

(22) Filed: Dec. 8, 2015

Related U.S. Application Data
(60) Provisional application No. 62/089,478, filed on Dec. 9, 2014.

(51) Int. Cl. C23C 16/455

(52) U.S. Cl. CPC C23C 16/455

(57) ABSTRACT

Certain exemplary embodiments can provide a system, which can comprise depositing a filament and a vapor flux that emanates from one or more vapor sources. The vapor flux is directed toward the filament via a carrier gas in a coating chamber under vacuum. The carrier gas can substantially surround the vapor flux as the filament is exposed to a coating material comprised by the vapor flux. Wherein the filament moves relative to the vapor flux.

### CROSS-REFERENCES TO RELATED APPLICATIONS

This application claims priority to, and incorporates by reference herein in its entirety, pending U.S. Provisional Patent Application Ser. No. 62/089,478, filed Dec. 9, 2014. This application is related to issued U.S. Pat. No. 7,014,889 (having an issue date of Mar. 21, 2006), which is incorporated by reference in its entirety.

### BRIEF DESCRIPTION OF THE DRAWINGS

A wide variety of potential practical and useful embodiments will be more readily understood through the following detailed description of certain exemplary embodiments, with reference to the accompanying exemplary drawings in which:

FIG. 1 is a block diagram of two exemplary systems 1000;

FIG. 2 is a photograph 2000 of a copper coated steel wire coated in a DVD environment using a substantially vertical orientation;

FIG. 3 is a block diagram of an exemplary system 3000;

FIG. 4 is a photograph 4000 of an aluminum NLOS coating using a DVD technique onto a stationary steel substrate;

FIG. 5 is a block diagram of an exemplary two part coating approach 5000 for a semi-uniformly coated cylindrical substrate;

FIG. 6 is a block diagram of an exemplary system 6000;

FIG. 7 is a block diagram of an exemplary system 7000;

FIG. 8 is a schematic illustration 8000;

FIG. 9 is a schematic illustration 9000;

FIG. 10 is a schematic illustration 10000;

FIG. 11 is a schematic illustration 11000;

FIG. 12 is a schematic illustration 12000 showing a composite fiber;

FIG. 13 is a schematic illustration 13000 showing a carbon nanotube fiber or tape; and

FIG. 14 is a flowchart of an exemplary embodiment of a method 14000.

### DETAILED DESCRIPTION

Electrically conducting wires are produced from pure metals having high electrical conductivity. Metals used for electrically conducting wires can comprise copper, aluminum, silver, gold, nickel, and/or magnesium. To obtain a combination of conductivity, weight, strength, flex fatigue resistance and flexibility, conducting wires can have several forms including monolithic wires (for example pure copper wires), multi-strand wire bundles and bi-layered wires consisting of two metals (for example—copper clad steel wires). Certain exemplary embodiments result in lighter weight wires having enhanced strength, flex fatigue resistance, and flexibility while retaining acceptable conductivity. Certain exemplary embodiments comprise composite wires in which polymer, polymer matrix composite, glass, carbon, carbon nanotube or ceramic fibers, tapes, and/or woven fabric substrates are coated with conducting metals to enable the creation of novel conducting materials. Certain exemplary embodiments provide novel types of composite wires having advanced properties and an apparatus for the creation of such wires. Certain exemplary embodiments provide for the use of the apparatus for coatings fibers, wires, tubes, and/or tapes for a range of application. Such applications comprise conductive coatings onto nanotube or superconducting tapes; piezoelectric layers for energy harvesting applications, coating of optical fibers; coating of ceramic fibers for use in ceramic matrix composites; anode, cathode or electrolyte layers of batteries; and/or cladding tubes for nuclear reactor fuel.

Certain wires are based on coating conductive metals onto fiber substrates comprising the application of relatively thin layers of conducting metals such as copper or nickel onto a relatively fine diameter (less than approximately 20 microns in diameter) polymeric or carbon fibers. These wires reduce the weight of the wire and increase the strength. However, the conductivity of such wires can be relatively low making them unsuitable for many current conducting applications unless relatively thick metal layers are applied onto these fibers. A relatively high amount of attenuation can be observed when alternating currents are applied to wires without thick metal layers. Flex fatigue performance of these materials can also be less than desired absent good adhesion of the coated metal. Where de-adhesion of the coated metal occurs during flexing, resulting debris can promote fiber failures. Certain exemplary embodiments provide for the formation of composite wires that have relatively light weight, high strength, improved flex fatigue resistance and electrical conductivity approaching that of current copper wiring.

Certain exemplary embodiments:
use a novel, directed vapor deposition process which allows for the high rate deposition of metals onto complex substrates;
provide a substantially continuous substrate (fibers, tapes, tubes, fabrics, felts) handling apparatus that enables the highly efficient deposition of metals for high rate and high throughput coating; and/or
use novel substrate combinations.

The successful application of metals onto the surface of long, small diameter filaments at ultra-high deposition rates can utilize several key elements. These comprise an ability to create a high volume of vapor having a suitable composition, an ability to efficiently apply the coating onto the required substrate and a large deposition area. Additionally, manufacturing systems based on such a vapor deposition approach can utilize moderate vacuums and, in some embodiments, the process can be made to operate in a substantially continuous manner. Attributes of a directed vapor deposition (“DVD”) process can utilize electron beam evaporation as an efficient means to create large volumes of vapor, the gas jet assisted nature of exemplary processes enable highly efficient deposition at moderate vacuums. Such systems reduce cost and equipment compared to other systems and/or methods associated with manufacturing at ultra-high vacuum levels. Certain exemplary DVD systems also enable substantially continuous coating operation concepts using differentially pumped chamber feed-through approaches or reel-to-reel processing.

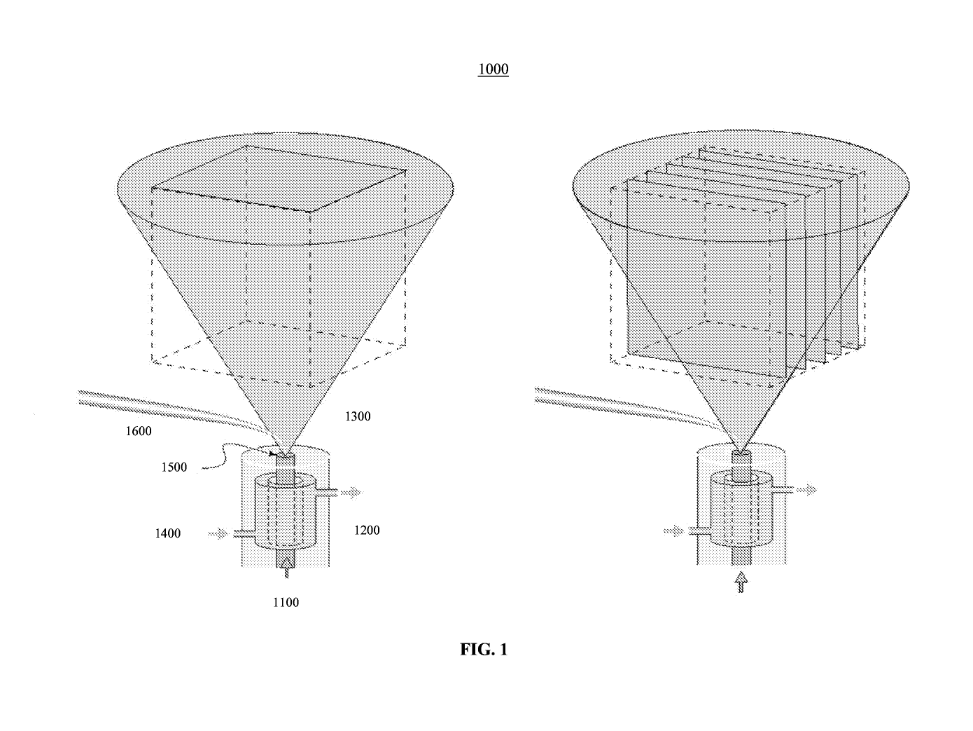

Certain exemplary embodiments incorporate a substrate handling apparatus that enable very large coating deposition areas while retaining the other advantageous aspects of the process. Certain exemplary embodiments provide techniques for coating zone scaling for production scale DVD coating. Additional improvements can be realized if substrates can be substantially uniformly coated without the need to perform complex (i.e. greater than one dimensional) substrate manipulation and/or coatings can be effectively applied onto non-line-of-sight (“NLOS”) regions of substrates. NLOS coating can provide substantially uniform coatings around fibers via manipulation of fiber substrate arrays in substantially a single dimension (“1D”) (i.e. translation with rotation). Certain exemplary embodiments utilize three dimensions of a vapor flux for deposition (see, e.g., FIG. 1). FIG. 1 is a block diagram of two exemplary systems 1000. An increased area can be coated in a given time when using NLOS deposition since the three-dimensional (“3D”) volume of the vapor flux can be utilized rather than a two-dimensional (“2D”) area. System 1000 comprises a continuous target feed 1100, a copper crucible 1200, a vapor flux 1300, a flow of coolant 1400, an evaporation target 1500, and a bent electron beam 1600.

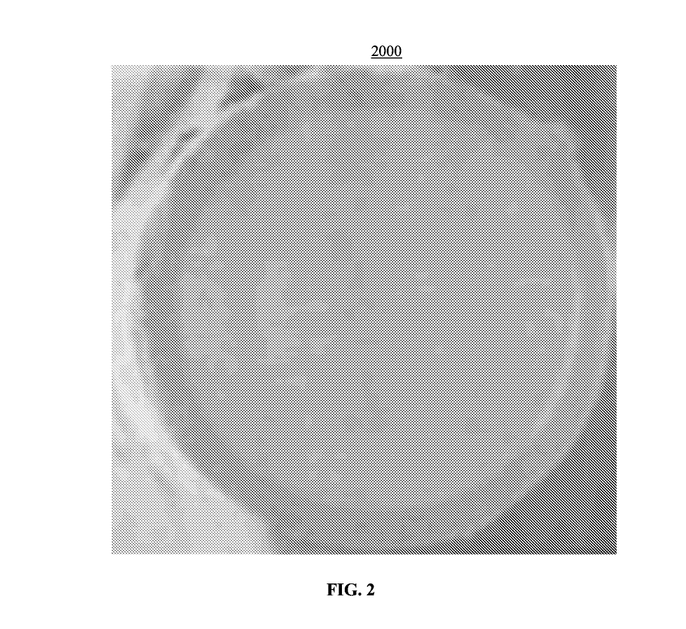

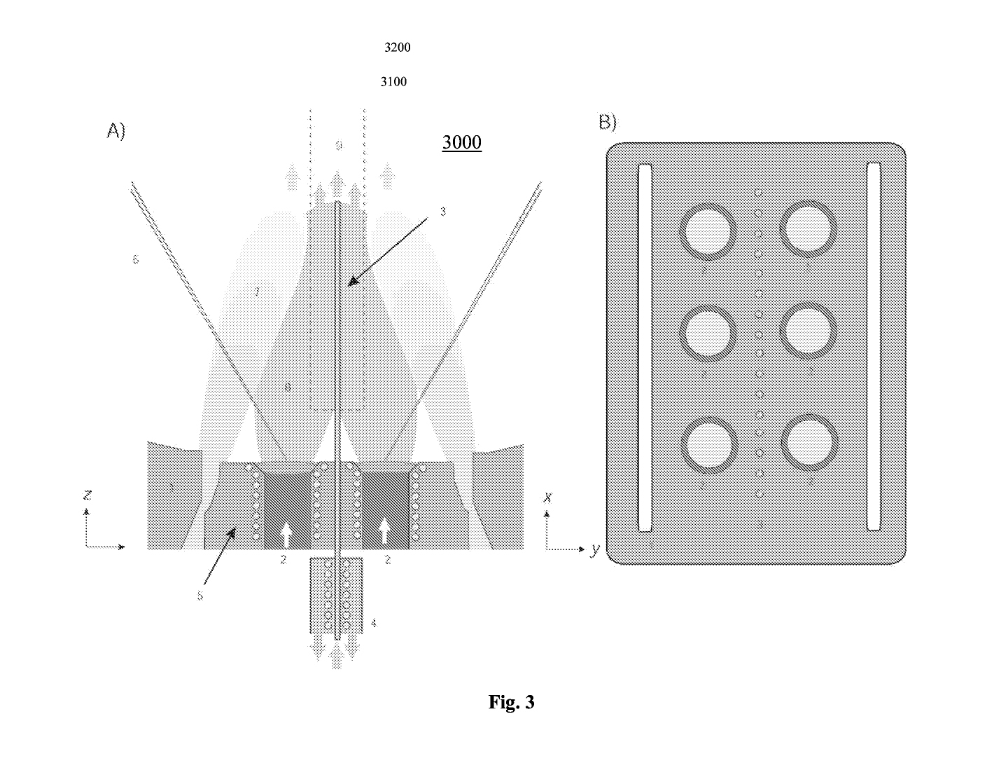

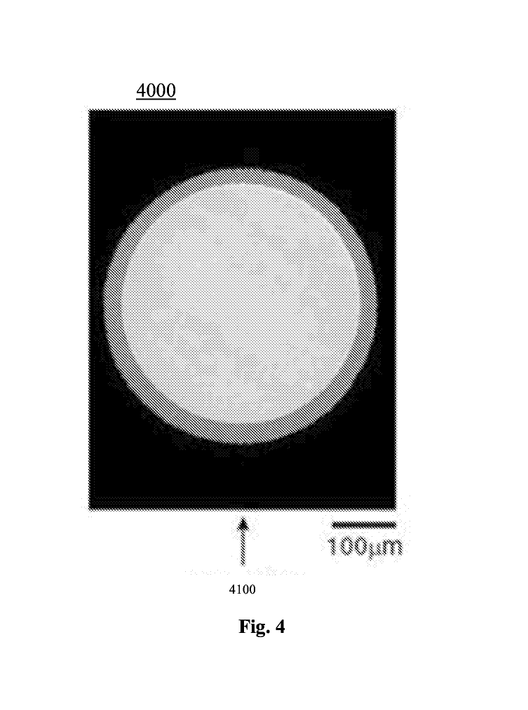

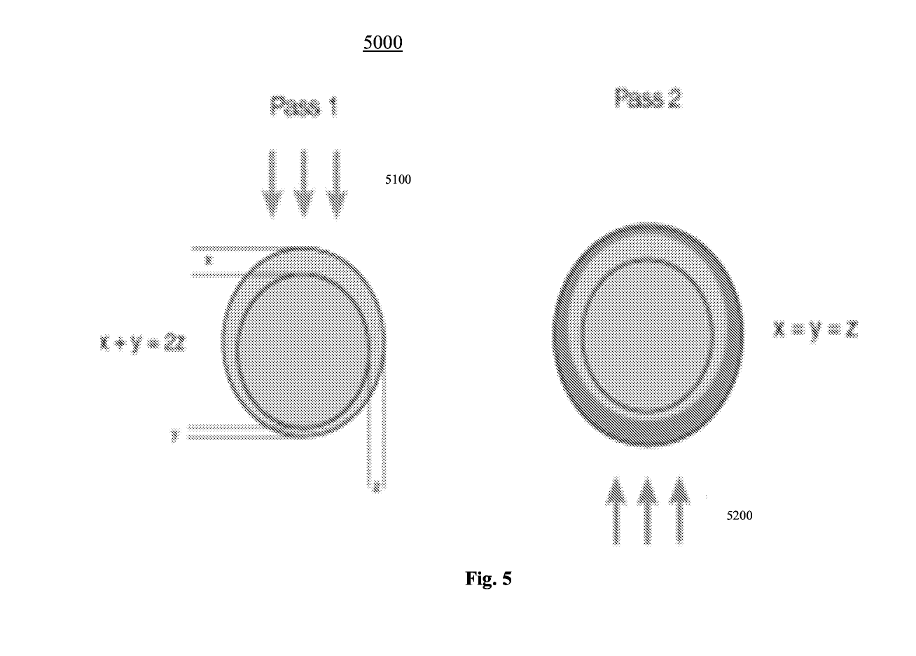

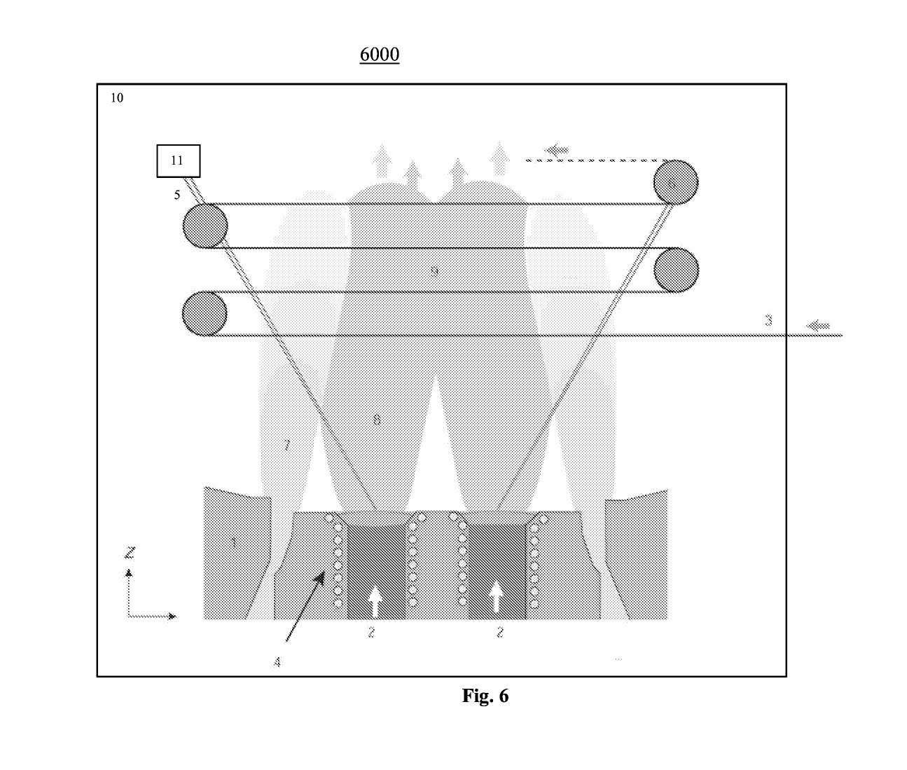

Certain exemplary DVD processes have been demonstrated to have an ability to apply substantially uniform dense layers onto vertically aligned cylindrical substrates (see, e.g., FIG. 2). FIG. 2 is a photograph 2000 of a copper coated steel wire coated in a DVD environment using a substantially vertical orientation. When combined the other attributes listed above (e.g., moderate vacuum enabled continuous evaporation) certain exemplary coating apparatuses provide for relatively high throughput manufacturing. Certain exemplary embodiments provide relatively large coating zones (for example the coating zone could extend many, many meters above the evaporation sources), which can be used to simultaneously coat multiple fibers, tapes or tubes in a substantially continuous manner (see, e.g., FIG. 3). FIG. 3 is a block diagram of an exemplary system 3000 showing a potential high throughput coating process for small diameter fibers using vertical translation. System 3000 comprises a gas jet nozzle 1, a source material 2, a substrate 3, an optional substrate pre-heater 4, a crucible 5, an electron beam 6, an inert gas 7, a vapor flux 8, and a coating zone 9. The ability to apply coatings onto horizontally aligned metal fibers and/or wires has also been demonstrated with the coating thickness on the NLOS side of the substrate as high as 70% of the line-of-sight coating thickness obtained, as shown in FIG. 4. FIG. 4 is a photograph 4000 of an aluminum NLOS coating using a DVD technique onto a stationary steel substrate. Photograph 4000 illustrates a vapor flux 4100. In this case, a multi-pass coating approach, such as shown in FIG. 5, in which the fiber orientation changes by approximately 180 degrees each pass can be used to create very uniform coating along the diameter of the fiber. FIG. 5 is a block diagram of an exemplary two part coating approach 5000 for a semi-uniformly coated cylindrical substrate. Two part coating approach 5000 illustrates a vapor flux 5100. The continual passing of a fiber array through the flux takes advantage of the three dimensional aspect of the process to potentially enable very high fiber coating throughout, as shown in FIG. 6. FIG. 6 is a block diagram of an exemplary system 6000 showing a potential high throughput coating process for small diameter fibers, wires and tapes using a multi-pass approach and horizontal translation. System 6000 comprises a gas jet nozzle 1, a source material 2, a substrate 3, a crucible 4, an electron beam 5, a fiber handling system 6, an inert gas 7, a vapor flux 8, a coating zone 9, and a chamber 10. When system 6000 is operational, chamber 10 can be under vacuum, such as a moderate vacuum level.

The non-line-of-sight (“NLOS”) coating attributes of exemplary DVD processes can also be utilized to create a filament (e.g., tape) coating apparatus with improved throughput. In certain physical vapor deposition (“PVD”) based processing approaches, deposition onto inclined surfaces (having limited line-of-sight access to the vapor source) results in poor film quality due to the impact of vapor atoms at highly oblique angles and from predominately one general direction. For surfaces that are non line-of-sight to the source, virtually no deposition occurs. This arises because the vapor atoms are created in a high vacuum that results in nearly collisionless vapor transport to the substrate. As a result, vapor atoms move in substantially straight paths emanating from the vapor source and substrate regions in the line-of-sight of the source receive virtually all atoms that coat the substrate.

Using the non-line-of-sight coating attributes of exemplary DVD processes, it has been demonstrated for several materials systems (yttria-stabilized zirconia, Al, Cu, Ta) that films can be created on inclined and NLOS surfaces that have a similar microstructure as those deposited onto line-of-site (“LOS”) locations. The basis for this ability is that the gas jet used in the DVD process allows vapor atoms to be directed parallel to inclined surfaces under conditions which promote their lateral diffusion onto the substrate via binary collisions. The random nature of such collisions results in the impact of vapor atoms over a wide range of directions (instead of one general direction) reducing shadowing effects and resulting in high quality films on inclined surfaces.

This fundamental difference creates the opportunity to utilize the vapor flux in ways not possible in conventional PVD approaches. Certain exemplary embodiments provide high throughput tape production in which a three dimensional area of the vapor flux is utilized rather than just a single cross sectional cut, such as illustrated in the leftmost system of FIG. 1. Expanded exploitation of the vapor flux in certain DVD processes enable either multiple tape lines to be passed through the flux or repeatedly circulating a single tape through a vapor flux plume for ultra-high tape translation speeds. Such an approach also allows the simultaneous coating of both sides of a substrate tape placed edgewise in the vapor flux plume. The result is a manifold increase in the cross-sectional area of a tape that can be coated in a given time and the tape throughput can be increased without substantially altering the deposition rate.

The combination of the vapor focusing and NLOS coating effects results in highly efficient use of the vapor flux. For small substrates such as fibers or wires, this enables an approximately 50 to 100 fold increase in deposition efficiency. For larger substrates, the increase is less (approximately 10 to 20 fold) but is achieved over a larger area. In order to take advantage of these effects an exemplary process can either tightly focus the vapor onto relatively small areas achieving ultra-high (greater than approximately 80 microns/minute) deposition rates locally or use the jet to tailor the vapor flux to the size of a substrate. In the former case, small, low cost coaters that still retain moderate coating throughputs can be utilized. In the latter, multiple crucibles and/or nozzles can be used to enable the vapor flux volume to be manipulated. Certain exemplary embodiments balance of coating throughput and capital cost. The “sweet spot” for this balance can be dependent on the application, however, the flexibility by the DVD approach can result in a significantly reduced deposition cost.

The attributes of this approach can be demonstrated by comparing the two approaches given in FIG. 1. In the first case (the leftmost system illustrated in FIG. 1), vapor deposition occurs substantially in a LOS manner. For a vapor flux of a given area with this constraint, the area of a substrate that can be coated at a given time is determined by the size and geometry of the vapor flux and substrate. Over this area the desired material will be coated at a given rate to define the coating thickness obtained upon exposure of the substrate for a given time.

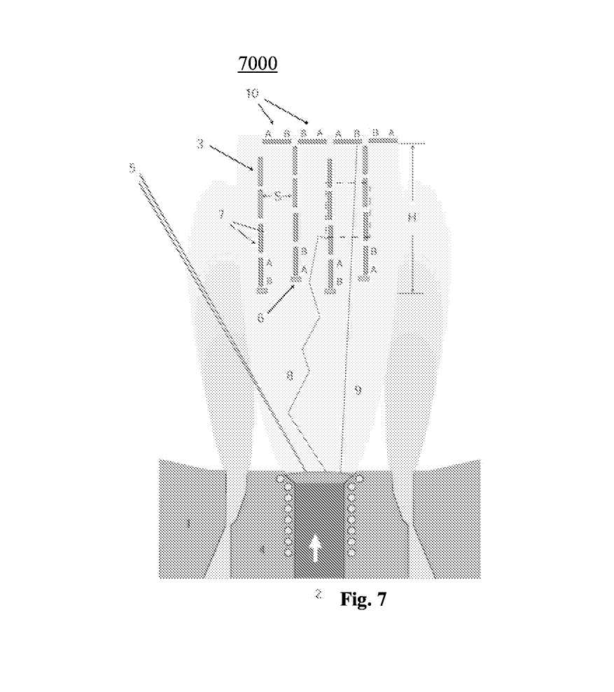

In the second case (the rightmost system illustrated in FIG. 1), vapor deposition can occur in both a LOS and NLOS manner. For a vapor flux of a given area with these constraints it is possible to coat tapes not only on the “end” of the created flux of vapor by also on the “interior” of the vapor flux. In such embodiments, the area of tape coated is dependent upon not the cross-sectional area of the flux but the volume of flux and the area of tape that can be intersected through this volume. This area is dependent on the spacing between the tapes and the height, of the tapes within the flux volume. These parameters determine the ultimate throughput benefits of this approach (along with the deposition rates achievable) and their optimal values can be experimentally determined. Certain exemplary embodiments utilize geometries such as shown in FIG. 7, which result in a throughput improvement that is approximately five to eight fold depending on the deposition rates obtainable on the vertically aligned films (these deposition rates can be approximately 0.5 to 1.0 times those of a line-of-sight arrangement). FIG. 7 is a block diagram of an exemplary system 7000 showing the incorporation of vertically aligned tapes into the vapor flux in the DVD system. In system 7000, the spacing between the tapes, S, the height of the deposition zone, H, and the deposition rate onto the vertical tapes determine the performance advantage over the use of strictly LOS processes. The use of gas jet focusing for the case shown can result in a throughput that is approximately two to five times greater than certain thermal evaporation processes due to increased vapor flux deposition focusing and that is approximately five to eight times greater from the use of NLOS deposition resulting in an overall throughput that is approximately ten to forty times greater than certain thermal evaporation processes. System 7000 comprises a gas jet nozzle 1, a source material 2, a substrate 3, a crucible 4, an electron beam and/or plasma source 5, a fiber handling system 6, an inert gas 7, a vapor flux 8, and a coating zone 9.

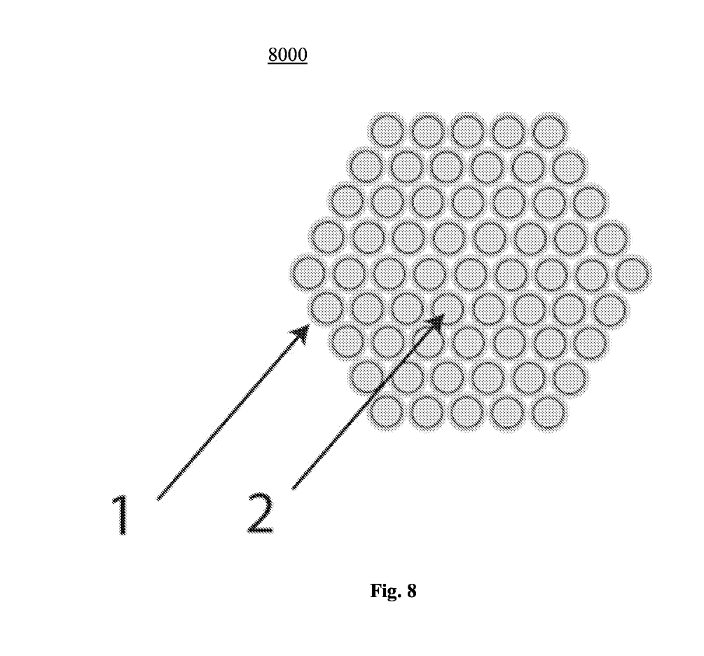

Wires based on coating conductive metals onto fiber substrates can be made via an application of relatively thin layers of conducting metals such as copper or nickel onto fine diameter (less than approximately 20 microns in diameter) polymeric or carbon fibers, such as illustrated in FIG. 8. FIG. 8 is a schematic illustration 8000 showing fine diameter (less than approximately 20 microns), polymer fibers 2, each having electrically conductive metal coating 1. These materials reduce the weight compared to copper wire and increase the strength. However, with thin layers of coating, the conductivity of certain such wires can be low making them unsuitable for many current conducting applications. Further, a relatively high amount of attenuation has been observed when alternating currents are applied certain small diameter wires with relatively thin metal coatings. The flex fatigue performance of such wires can be relatively low due to poor adhesion of the coated metal. De-adhesion of the coated metal during flexing can result in debris that can promote fiber failures.

Improved performance may be achieved by using thicker metal coatings applied onto several different types of substrates. These include:

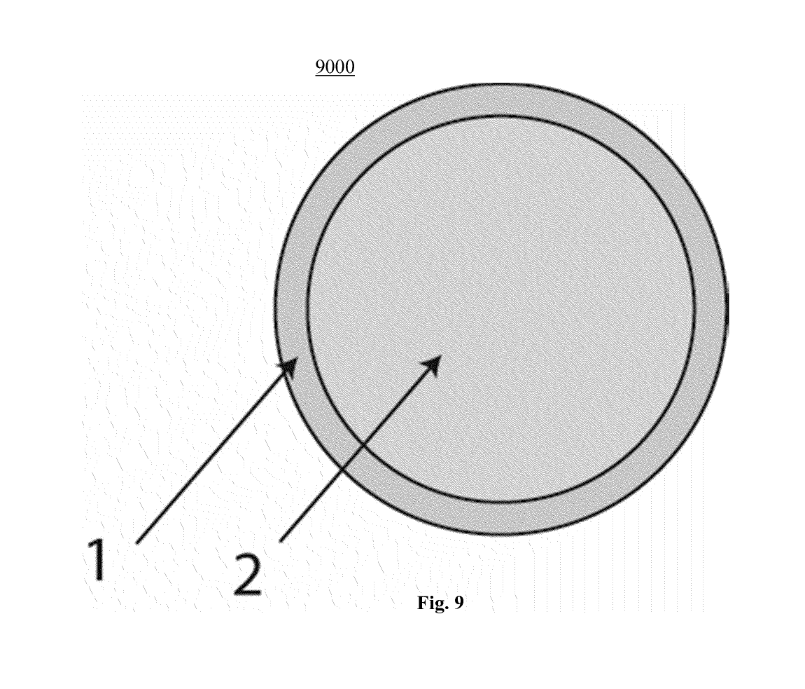

The use of larger diameter polymer fibers (in the range of approximately 20 to approximately 500 microns) as a substrate as shown in FIG. 9. FIG. 9 is a schematic illustration 9000 showing a monolithic polymer fiber 2 having an electrically conductive metal coating 1. Fibers based on low elastic modulus polymers; such as polyether ether ketone (“PEEK”), High-density polyethylene (“HDPE”), Telfon (Teflon is a registered trademark of E.I. DuPont De Nemours and Company, 1008 Market Street, Wilmington, Del.) and/or polybenzimidazole (“PBI”—PBI is a registered trademark of PBI Performance Products, Inc. 9800-D Southern Pine Blvd, Charlotte, N.C. 28273), etc.; can have (1) similar or greater tensile strength and ductility as copper, (2) a coated fiber that has enhanced electrical conductivity over coated small diameter fibers (due to a larger volume fraction of coated metal, and reduced signal attenuation), and/or (3) a similar or enhanced flex fatigue resistance despite the larger fiber diameter (due to the low elastic modulus of the composite fiber).

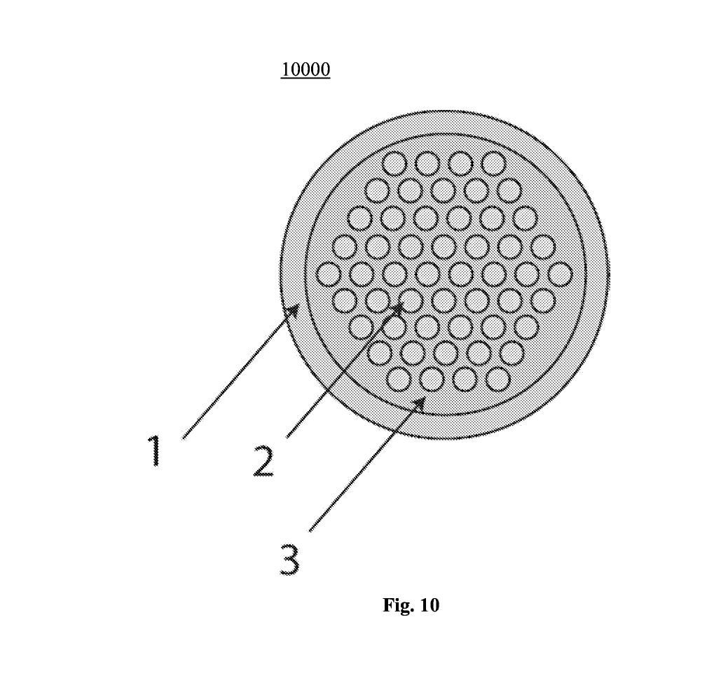

In certain exemplary embodiments utilizing larger diameter polymer fibers, high strength fibers can be incorporated into a polymeric monofilament to form a polymer matrix composite fiber, see FIG. 10. FIG. 10 is a schematic illustration 10000 showing a monolithic polymer matrix composite fiber (comprising a polymer matrix 3 and reinforcing fibers 2) having an electrically conductive metal coating 1. In this case, a moderate strength, high ductility matrix material; for example, Teflon, PBI, PEEK, and/or HDPE, etc.; and a high strength fiber; such as Kevlar (Kevlar is a registered trademark of E.I. DuPont De Nemours and Company, 1007 Market Street, Wilmington, Del.), para-amide, Zylon (Zylon is a registered trademark of Toyo Boseki Kabushiki Kaisha, Ta Toyobo Co., Ltd., No. 2-8, Dojima Hama 2-chome, Kita-ku Osaka Japan), E-glass (i.e., alumino-borosilicate glass with less than 1% w/w alkali oxides), S-glass (i.e., alumino silicate glass without CaO but with high MgO content), Nextel (Nextel is a registered trademark of 3M Co., 3M Center 2501 Hudson Road, St. Paul Min.), carbon, carbon nanotube and/or other fibers, etc.; can be combined. When coated with a conductive metal, the resulting material can have (1) similar or greater tensile strength and ductility as copper, (2) a coated fiber that has enhanced electrical conductivity over coated small diameter fibers (due to a larger volume fraction of coated metal, and reduced signal attenuation), and/or (3) an enhanced flex fatigue resistance despite the larger fiber diameter (due to the low elastic modulus of the composite fiber).

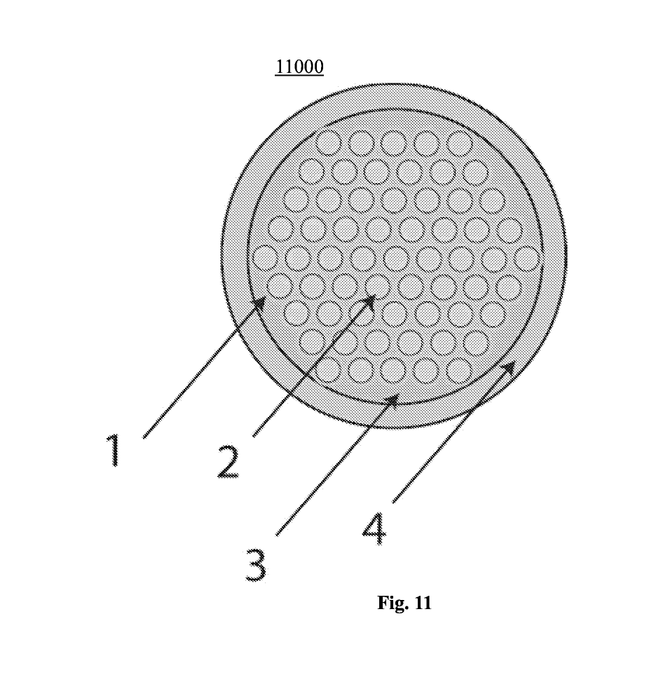

Fibers incorporated into a polymer matrix, as shown in FIG. 10, can comprise a coating of a conductive metal. The substrate shown in FIG. 11, can have (1) similar or greater tensile strength and ductility as copper, (2) a coated fiber that has enhanced electrical conductivity over coated small diameter fibers (due to a larger volume fraction of coated metal, and reduced signal attenuation), (3) a similar or enhanced flex fatigue resistance despite the larger fiber diameter (due to the low elastic modulus of the composite fiber), and/or (4) better low frequency electrical conductivity. FIG. 11 is a schematic illustration 11000 showing a monolithic polymer matrix composite fiber, which comprises an electrically conductive metal coating 4, a polymer matrix 3, and reinforcing fibers 2 each of which comprises a metal coating 1.

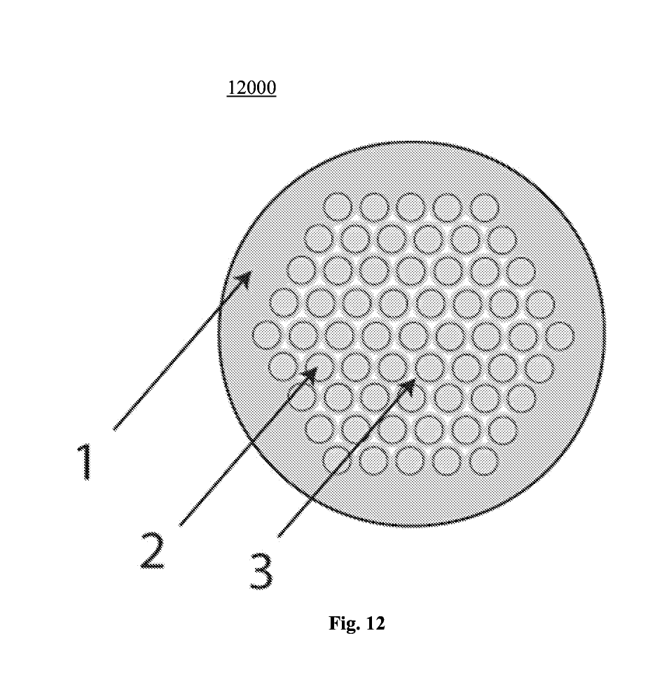

Metal coated fibers can be coated with a thick outer layer of a conducting material. The substrate shown in FIG. 12, can have a better low frequency electrical conductivity than certain embodiments utilizing polymer fiber monofilaments or polymer matrix composite fibers due to the larger volume fraction of conductive metal above and a better flex fatigue resistance than the baseline (see, FIG. 8). FIG. 12 is a schematic illustration 12000 showing a composite fiber, which comprises a metal coating 3 on each of a plurality of reinforcing fibers 2 and an electrically conductive metal coating 1.

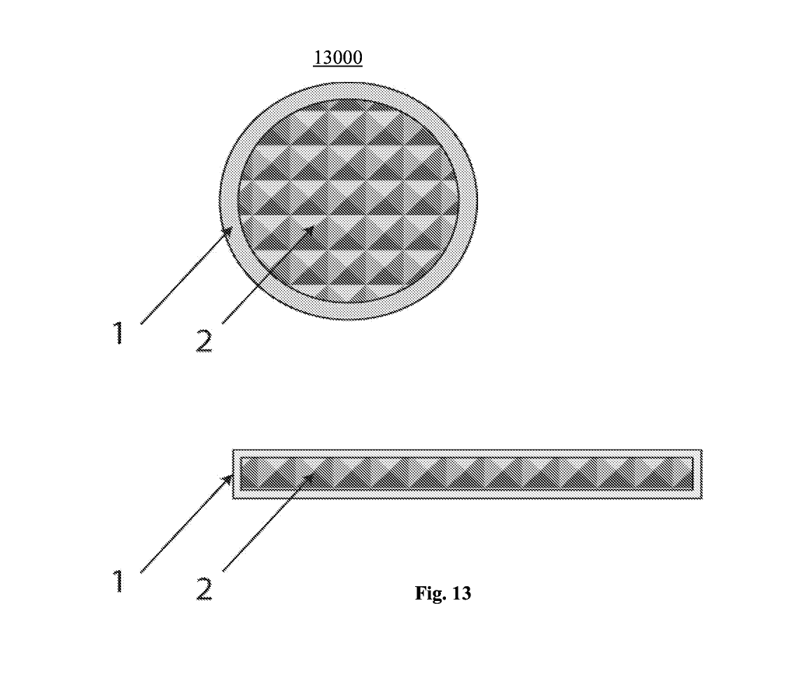

Fibers and tapes (and other materials) created from carbon nanotubes (“CNT”) can provide improved flex fatigue performance and/or additional weight reductions over coated polymer based fibers and enhanced strength. However, such materials have a significantly lower electrical conductivity (greater than an order of magnitude) than the most conductive metals. Using the fibers and tapes as a substrate for electrically conductive coatings provides a means to make use of the excellent mechanical properties of these materials while improving upon the low frequency electrical conductivity of the uncoated CNT substrates, see FIG. 13. For example, coating a CNT fiber or tape can provide a slightly higher (5 to 10%) low frequency electrical conductivity than embodiments utilizing polymer fiber monofilaments due to the conductivity of the CNT material and improved flex fatigue and strength performance due to the excellent mechanical properties of CNT fibers and tapes. The high frequency electrical conductivity of the coated CNT fibers and tapes can be much greater than uncoated due to “skin effects” present at high frequency. FIG. 13 is a schematic illustration 13000 showing a carbon nanotube fiber or tape 2, which comprises an electrically conductive metal coating 1.

Additional applications for certain exemplary embodiments can comprise:

conductive coatings for superconducting tapes and fibers;
oxidation and environmental protection coatings for nuclear fuel cladding;
coatings of ceramic fibers used to creation ceramic matrix composites; and/or
metal coatings onto optical fibers to enable higher temperature application and other benefits.

Certain exemplary embodiments comprise a filament, such as:
substrate 3 of FIG. 3;
substrate 3 of FIG. 6;
substrate 3 of FIG. 7;
polymer fibers 2 of FIG. 8;
polymer fiber 2 of FIG. 9;
reinforcing fibers 2 of FIG. 10;
reinforcing fibers 2 of FIG. 11;
reinforcing fibers 2 of FIG. 12;
carbon nanotube fiber or tape 2 of FIG. 13;
a fiber;
a wire;
a metal wire;
or a tape.

Certain exemplary embodiments comprise a vapor flux that emanates from one or more vapor sources. The vapor flux, such as vapor flux 8 of FIG. 3, is directed toward the filament via a carrier gas, such as inert gas 7 of FIG. 3, in a coating chamber, such as chamber 10 of FIG. 6, under vacuum. The carrier gas can substantially surrounding the vapor flux as the filament is exposed to a coating material, such as evaporated and/or sublimated source material 2 of FIG. 3, comprised by the vapor flux. In certain exemplary embodiments, the filament moves relative to the vapor flux.

Certain exemplary embodiments comprise an intermediate chamber, such as can be comprised by substrate pre-heater 4 of FIG. 3. The intermediate chamber can be maintained at a vacuum level between atmospheric pressure and a vacuum level of the coating chamber. In certain exemplary embodiments, the filament enters the intermediate chamber prior to entering the coating chamber.

Certain exemplary embodiments comprise:
a plasma source, such as plasma source 5 of FIG. 7, that ionizes at least a portion of the coating material and carrier gas;
a pre-heater, such as substrate pre-heater 4 of FIG. 3, that transfers heat energy to the filament; and/or
an electron beam source, such as electron beam source 11 of FIG. 6, that supplies an electron beam that evaporates or sublimates the coating material.

In certain exemplary embodiments:
the filament moves back and forth relative to the vapor flux such that the substantially uniform layer is formed;
the filament moves back and forth and rotates relative to the vapor flux such that the substantially uniform layer is formed;
the carrier gas is directed in the chamber via a gas jet nozzle;
the filament is a metal wire;
the filament comprises carbon;
the filament comprises polymer fibers;
the filament comprises carbon nanotubes;
the filament comprises polymer matrix composite fibers;
the filament comprises a fiber optic cable;
the filament comprises a glass;
the filament is coated by a coating material comprising a metal, alloy, or ceramic material, wherein the vapor flux comprises the coating material;
the filament comprises multiple layers applied via the system with each layer comprising one or more of a metal, an alloy or a ceramic material;
the coating material comprises an electrically conductive metal or alloy;
the coating material comprises an anode, cathode or electrolyte layer of a battery;
the coating material comprises an piezoelectric material;
the coating material is boron nitride;
the coating material is deposited as a substantially uniform layer on the filament via non-line of sight coating of at least a portion of the filament;
after being coated by the system, the filament is superconductive;
after being coated by the system, the filament is usable as a nuclear fuel cladding; and/or
the filament is a ceramic fiber, which can comprise silicon carbide, silicon nitride, alumina, silica, and/or mixtures thereof, etc.

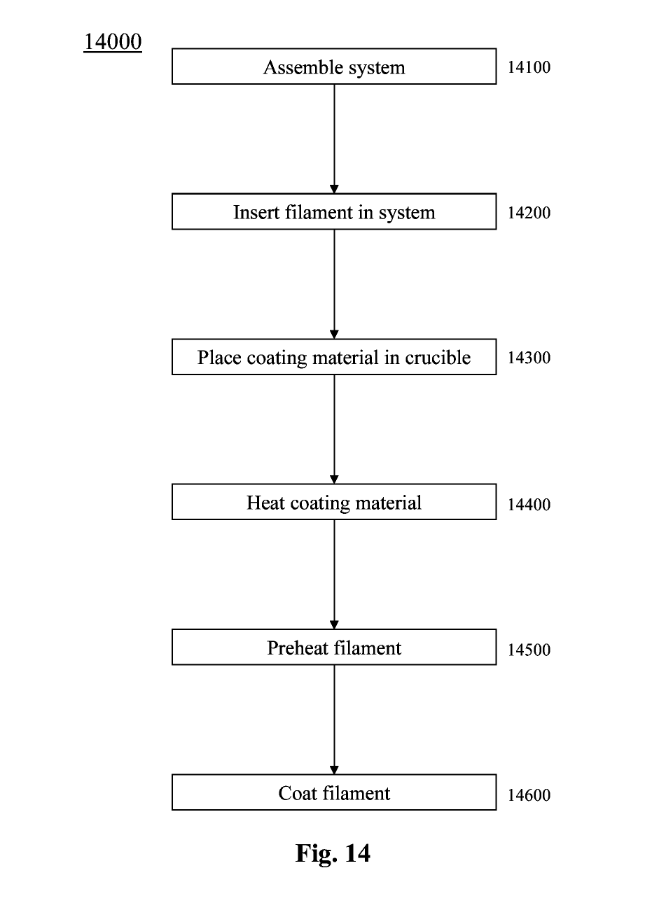

FIG. 14 is a flowchart of an exemplary embodiment of a method 14000. At activity 14100, a system can be assembled. The system can comprise a source material, a crucible, a gas jet nozzle, a substrate (e.g., a filament), a substrate pre-heater, an electron beam, a plasma source, a fiber handling system, an inert gas, a vapor flux, a vacuum chamber, and/or a coating zone.

At activity 14200, a filament can be inserted in the system. The filament can be substantially continuous. The filament can comprise a polymer fiber monofilament, a polymer matrix composite fiber, a composite fiber, a carbon nanotube fiber, and/or a carbon nanotube tape, etc.

At activity 14300, a coating material can be placed in the crucible.

At activity 14400, the coating material can be heated to generate a vapor flux that can be comprised by a vapor flux.

At activity 14500, the filament can be preheated.

At activity 14600, the filament is coated. Certain exemplary embodiments cause a substantially uniform coating to be deposited on a filament. The coating is deposited via a vapor flux that emanates from one or more vapor sources. The vapor flux is directed toward the filament via a carrier gas in a chamber under vacuum. The carrier gas substantially surrounds the vapor flux as the filament is exposed to the vapor flux. In certain exemplary embodiments, the filament moves relative to the vapor flux, such as via a fiber handling system.

### Definitions

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.
a—at least one.
activity—an action, act, step, and/or process or portion thereof.
adapter—a device used to effect operative compatibility between different parts of one or more pieces of an apparatus or system.
air—a mixture of nitrogen, oxygen, and other gases that surround the earth and form its atmosphere.
alloy—a substance comprising two or more metals.
and/or—either in conjunction with or in alternative to.
angle—a geometric figure formed by two lines that begin at a common point or by two planes that begin at a common line. The space between such lines or planes, measured in degrees.
annular—ring shaped.
apparatus—an appliance or device for a particular purpose
associate—to join, connect together, and/or relate.
atmospheric pressure—a value of standard atmospheric pressure, equivalent to the pressure exerted by a column of mercury of approximately 29.92 inches.
automatically—acting or operating in a manner essentially independent of external influence or control. For example, an automatic light switch can turn on upon “seeing” a person in its view, without the person manually operating the light switch.
bias—a voltage or current applied to an electrical device and/or system.
can—is capable of, in at least some embodiments.
carbon nanotube—a hollow substantially cylindrical or toroidal molecule made substantially entirely of carbon.
carrier gas—a substance that acts to convey a coating material in a chamber, which substance is in a state such that the substance expands freely to fill any space available, irrespective of a quantity of the substance.
cause—to produce an effect.
ceramic—any of various hard, brittle, heat- and corrosion-resistant materials made typically of metallic elements combined with oxygen or with carbon, nitrogen, or sulfur.
chamber—a substantially enclosed space or cavity.
coat—to provide an object with a layer over a surface of the object.
coating material—a substance to be applied as a layer to a substrate surface.
coat—to apply a layer of a coating material on a substrate.
coaxial—having a common axis.
component—a part of a larger whole.
comprising—including but not limited to.
configure—to make suitable or fit for a specific use or situation.
connect—to join or fasten together.
constructed to—made suitable or fit for a specific use or situation.
convert—to transform, adapt, and/or change.
coupleable—capable of being joined, connected, and/or linked together.
coupling—linking in some fashion.
create—to bring into being.
crucible—a container constructed to hold a substance, which container is constructed to allow the substance to be subjected to a gasifying temperature.
define—to establish the outline, form, or structure of.
device—a machine, manufacture, and/or collection thereof.
deposit—to put a layer on a surface of an object.
directed vapor deposition—a method via which a layer of a coating material is put on a surface of a substrate, wherein the layer is formed via condensation of an evaporated substance on the surface of the substrate, which evaporated substance is conveyed to the surface of the substrate via a carrier gas stream. The coating material and/or carrier gas steam may pass through a plasma flux, but that is not necessarily a requirement.
directionality—indicating a direction in space.
electrically conductive—constructed to convey electricity over a distance and having a resistivity of less than approximately 1 mΩ cm.
electrically non-conductive—constructed to substantially not conduct electricity and having a resistivity of greater than approximately 1 mΩ cm.
electron beam source—a system that emits a directed electron stream.
emanate—to be emitted by.
emission direction—a primary course along which a plasma source conveys a plasma flux.
evaporate—to impart energy such that a solid or liquid changes to a gaseous state.
expose—to allow contact with.
fiber—a slender filament.
filament—a substrate, polymer fiber, reinforcing fiber, carbon nanotube fiber, fiber, wire, metal wire, carbon nanotube tape, or tape substrate having a length that is substantially greater than its width or thickness.
gas jet nozzle—a pipe or duct that directs a gas and accelerates the flow of the gas.
glass—any of various amorphous materials formed from a melt by cooling to rigidity without crystallization, such as, E-glass or S-glass.
heat energy—nonmechanical energy with reference to a temperature difference between a system and its surroundings or between two parts of the same system.
ionize—to convert (an atom, molecule, or substance) into an ion or ions, typically by removing one or more electrons.
install—to connect or set in position and prepare for use.
intermediate—situated between two other things and having at least one characteristic that is distinct from the two other things.
layer—a covering over a surface.
level—magnitude.
maintain—to keep in a specified state.
may—is allowed and/or permitted to, in at least some embodiments.
method—a process, procedure, and/or collection of related activities for accomplishing something.
monofilament—a single fiber filament.
move—to change position.
net—remaining after an interaction.
non-line-of-site—portions of something that are not visible to a human via observation from a fixed point in space.
nuclear fuel cladding—a coating of a rod used as a fuel source in a nuclear reactor.
parallel—extending substantially in a same direction, approximately equidistant at all points, and substantially not converging or diverging.
plasma—One of four main states of matter, similar to a gas, but consisting of positively charged ions with most or all of their detached electrons moving freely about.
plasma current—an electron flow applied to a plasma source
plasma flux—a flow of plasma from a plasma source.
plasma generated ions—positively charged atoms or molecules created and conveyed by a plasma source.
plasma source—a system constructed to impart energy to a coating material and thereby generate a plasma.
plurality—the state of being plural and/or more than one.
polarity—a relative direction of an electrical or magnetic field.
polymer—a compound of relatively high molecular weight derived either by the addition of many smaller molecules or by the condensation of many smaller molecules with the elimination of water, alcohol, or the like.
predetermined—established in advance.
pre-heater—a subsystem that heats something before that something is subjected to a further process.
pressure—a substantially continuous physical force exerted on or against an object by something in contact with the object.
pressure ratio—a quantitative relation between two pressures showing the number of times one pressure is when mathematically divided by the other.
probability—a quantitative representation of a likelihood of an occurrence.
provide—to furnish, supply, give, and/or make available.
pure—substantially of a single substance.
receive—to get as a signal, take, acquire, and/or obtain.
repeatedly—again and again; repetitively.
set—a related plurality.
stream—a flow of something.
sublimate—to transition directly from a solid to a gas phase without passing through an intermediate liquid phase.
substantially—to a great extent or degree.
substrate—a substance or layer upon which one or more predetermined layers are deposited.
superconductive—having substantially no electrical resistance, and having an ability to carry electric current with substantially no loss of energy.
support—to bear the weight of, especially from below.
switch—to change.
system—a collection of mechanisms, devices, machines, articles of manufacture, processes, data, and/or instructions, the collection designed to perform one or more specific functions.
thickness—a distance between opposite sides of an object.
transfer—to go from one thing to another.
uniform—having a thickness that is within approximately ten percent of being the same over a surface.
uniform access—having a substantially equal probability of being deposited in a given location as compared to any other location on a surface.
vacuum—a pressure that is lower than atmospheric pressure.
vapor flux—a flow of a substance that comprises a coating material in a chamber, which substance is in a state such that the substance expands freely to fill any space available, irrespective of a quantity of the substance.
vapor source—a crucible from which gaseous stream emanates, the gaseous stream comprising a coating material to be applied as a layer to a substrate.
via—by way of and/or utilizing.
weight—a value indicative of importance.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.

Thus, regardless of the content of any portion (e.g., title, field, background, summary, description, abstract, drawing FIG., etc.) of this application, unless clearly specified to the contrary, such as via explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
no characteristic, function, activity, or element is “essential”;
any elements can be integrated, segregated, and/or duplicated;
any activity can be repeated, any activity can be performed by multiple entities, and/or any activity can be performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing FIG., etc.) of this application, other than the claims themselves, is to be regarded as illustrative in nature, and not as restrictive, and the scope of subject matter protected by any patent that issues based on this application is defined only by the claims of that patent.

What is claimed is:

1. A system comprising:
a filament;
a vapor flux that emanates from one or more vapor sources, said vapor flux directed toward said filament via a carrier gas in a coating chamber under vacuum, said carrier gas substantially surrounding said vapor flux as said filament is exposed to a coating material comprised by said vapor flux, wherein said filament moves relative to said vapor flux.

2. The system of claim 1, further comprising:
an intermediate chamber, said intermediate chamber maintained at a vacuum level between atmospheric pressure and a vacuum level of said coating chamber, wherein said filament enters said intermediate chamber prior to entering said coating chamber.

3. The system of claim 1, further comprising:
a plasma source that ionizes at least a portion of said coating material and carrier gas.

4. The system of claim 1, further comprising:
a pre-heater that transfers heat energy to said filament.

5. The system of claim 1, further comprising:
an electron beam source that supplies an electron beam that evaporates or sublimates said coating material.

6. The system of claim 1, wherein:
said filament moves back and forth relative to said vapor flux such that a substantially uniform layer is formed.

7. The system of claim 1, wherein:
said filament moves back and forth and rotates relative to said vapor flux such that a substantially uniform layer is formed.

8. The system of claim 1, wherein:
said carrier gas is directed in said chamber via a gas jet nozzle.

9. The system of claim 1, wherein:
said filament is a metal wire.

10. The system of claim 1, wherein:
said filament comprises carbon.

11. The system of claim 1, wherein:
said filament comprises a glass.

12. The system of claim 1, wherein:
said filament comprises polymer fibers.

13. The system of claim 1, wherein:
said filament comprises carbon nanotubes.

14. The system of claim 1, wherein:
said filament comprises polymer matrix composite fibers.

15. The system of claim 1, wherein:
said filament is coated by a coating material comprising a metal, alloy, or ceramic material, wherein said vapor flux comprises said coating material.

16. The system of claim 1, wherein:
said filament comprises multiple layers applied via said system with each layer comprising one or more of a metal, an alloy or a ceramic material.

17. The system of claim 1, wherein:
said coating material comprises an anode, cathode or electrolyte layer of a battery.

18. The system of claim 1, wherein:
said coating material comprises an piezoelectric material.

19. The system of claim 1, wherein:
said coating material is boron nitride.

20. The system of claim 1, wherein:
said coating material is deposited as a substantially uniform layer on said filament via non-line of sight coating of at least a portion of said filament.

21. The system of claim 1, wherein:
after being coated by said system, said filament is superconductive.

22. The system of claim 1, wherein:
after being coated by said system, said filament is usable as a nuclear fuel cladding.

23. The system of claim 1, wherein:
said filament is a ceramic fiber, said ceramic fiber comprising at least one of silicon carbide, silicon nitride, alumina, and silica.

24. A method comprising:
causing a substantially uniform coating to be deposited on a filament, said coating deposited via a vapor flux that emanates from one or more vapor sources, said vapor flux directed toward said filament via a carrier gas in a chamber under vacuum, said carrier gas substantially surrounding said vapor flux as said filament is exposed to said vapor flux, wherein said filament moves relative to said vapor flux.
